(19) United States
(12) Patent Application Publication
(10) Pub. No.: US 2023/0127783 A1
(43) Pub. Date: Apr. 27, 2023

(54) FIELD EFFECT TRANSISTOR WITH REDUCED SOURCE/DRAIN RESISTANCE

(71) Applicant: International Business Machines Corporation, Armonk, NY (US)

(72) Inventors: Tsung-Sheng Kang, Ballston Lake, NY (US); Oleg Gluschenkov, Tannersville, NY (US); Alexander Reznicek, Troy, NY (US); Ruilong Xie, Niskayuna, NY (US); Tao Li, Slingerlands, NY (US)

(21) Appl. No.: 17/512,647

(22) Filed: Oct. 27, 2021

(51) Int. Cl. H01L 29/45; H01L 29/417; H01L 29/78; H01L 29/40; H01L 21/24; H01L 29/66

(52) U.S. Cl. CPC H01L 29/45; H01L 29/41741; H01L 29/7827; H01L 29/401; H01L 21/244; H01L 29/66666

(57) ABSTRACT

A semiconductor structure includes a gate stack surrounding a semiconductor channel; a first semiconductor source/drain; a first metallic contact that touches the first source/drain; a second semiconductor source/drain; and a second metallic contact that touches the second source/drain. A conductive path length from the channel to the first metallic contact through the first source/drain is smaller than a conductive path length from the channel through the second source/drain to the second metallic contact. The second source/drain includes a bypass layer that touches the second metallic contact, and the bypass layer includes a metastable alloy of two or more elements of semiconductors and dopants.

### BACKGROUND

The present invention relates to the electrical, electronic, and computer arts, and more specifically, to field effect transistors (FETs) with epitaxial source/drain regions.

FETs make use of a varying electrical potential (gate voltage) to control flow of electrons or holes from a source to a drain. FETs are wired into electrical circuits by providing independent metallic contacts to the sources, drains, and gates that are connected by metallic wires according to circuit topology. In order to reduce the footprint of such circuits, some metallic source and drain contacts are placed in an asymmetric fashion such that at least one of these contacts is placed away from the FET gates, resulting in an increased source/drain (S/D) resistance.

### SUMMARY

Principles of the invention provide techniques with reduced bottom source/drain resistivity. In one aspect, an exemplary semiconductor structure includes a gate stack that surrounds a semiconductor channel; a first semiconductor source/drain; a first metallic contact that touches the first source/drain; a second semiconductor source/drain; and a second metallic contact that touches the second source/drain. A conductive path length from the channel to the first metallic contact through the first source/drain is smaller than a conductive path length from the channel through the second source/drain to the second metallic contact. The second source/drain includes a bypass layer that touches the second metallic contact, and the bypass layer includes a metastable alloy of two or more elements of semiconductors and dopants.

According to another aspect, an exemplary semiconductor structure includes a semiconductor substrate; a semiconductor fin protruding from the substrate; a top semiconductor layer at an upper end of the fin away from the substrate; a bottom semiconductor layer in the substrate adjacent to and partly underlying the fin; a gate stack surrounding vertical sides of the fin between the top semiconductor layer and the bottom semiconductor layer; an interlayer dielectric surrounding the fin and the gate stack; a metallic top contact penetrating the interlayer dielectric and touching the top semiconductor layer; a metallic gate contact penetrating the interlayer dielectric and touching the gate stack; a bypass layer partly underlying the fin and touching the bottom semiconductor layer; and a metallic bottom contact penetrating the interlayer dielectric and touching the bypass layer. The bypass layer includes a metastable alloy of two or more elements of semiconductors and dopants.

According to another aspect, an exemplary method includes forming an asymmetric semiconductor structure. The asymmetric semiconductor structure has a fin that has an upper portion and a base; a top source/drain structure that touches the upper portion of the fin; and a bottom source/drain structure that touches the base of the fin. The top source/drain structure is smaller than the bottom source/drain structure. The asymmetric semiconductor structure also includes a germanium-containing bypass layer within the bottom source/drain structure. The method further includes alloying the germanium-containing bypass layer with a dopant to form a metastable semiconductor-dopant alloy, forming a top metallic contact that touches the top source/drain structure at a first conductive path length from the fin, and forming a bottom metallic contact that touches the bypass layer at a second conductive path length from the fin. Although the second conductive path length is significantly longer than the first conductive path length, the bypass layer is effective to reduce resistance along the second conductive path length so that a resistance from the bottom metallic contact to the fin is nearly equal to a resistance from the top metallic contact to the fin.

In view of the foregoing, techniques of the present invention can provide substantial beneficial technical effects. For example, one or more embodiments provide one or more of:

Smaller parasitic resistance between bottom source/drain contact, channel, and top source/drain region. The cross-section of the bottom contact can be smaller because of smaller overall external resistance as the result of lower contact and bulk resistivity of the bypass layer, hence, leading to a higher areal density of transistors.

Some embodiments may not have these potential advantages and these potential advantages are not necessarily required of all embodiments. These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 depicts a top view of a vertical transport field effect transistor (VTFET), as seen from cut line 1-1 of FIG. 3.

FIG. 2 depicts a side view of the VTFET shown in FIG. 1, as seen from cut line 2-2 of FIG. 1.

FIG. 3 depicts a side view of the VTFET shown in FIG. 1, as seen from cut line 3-3 of FIG. 1.

FIG. 4 depicts a side view of a VTFET according to an exemplary embodiment, after bottom source contact formation.

FIG. 5 shows a flowchart of a process for fabrication of the VTFET shown in FIG. 4.

FIG. 6 depicts a precursor structure to a VTFET as shown in FIG. 4, before first liner reactive ion etch (RIE), as seen from cut line 6-6 in FIG. 4.

FIG. 7 depicts a precursor structure to the VTFET shown in FIG. 4, after first liner RIE, as seen from cut line 6-6.

FIG. 8 depicts a precursor structure to the VTFET shown in FIG. 4, after second liner deposition, as seen from cut line 6-6.

FIG. 9 depicts a precursor structure to the VTFET shown in FIG. 4, after RIE to break through the second liner, as seen from cut line 6-6.

FIG. 10 depicts a precursor structure to the VTFET shown in FIG. 4, after epitaxial growth of germanium (Ge), as seen from cut line 6-6.

FIG. 11 depicts a precursor structure to the VTFET shown in FIG. 4, after second liner strip and bottom epitaxial silicon (Si) growth, as seen from cut line 6-6.

FIG. 12 depicts a precursor structure to the VTFET shown in FIG. 4, after trench RIE, as seen from cut line 12-12 in FIG. 11.

FIG. 13 depicts a precursor structure to the VTFET shown in FIG. 4, after formation of shallow trench isolation (STI), bottom spacer, gate stack, top spacer and epitaxial silicon, top source/drain contact, and gate contact, as seen from cut line 12-12.

FIG. 14 depicts a precursor structure to the VTFET shown in FIG. 4, after RIE for bottom source/drain trench, as seen from cut line 12-12.

FIG. 15 depicts a precursor structure to the VTFET shown in FIG. 4, after boron doping the bottom source/drain trench, as seen from cut line 12-12.

FIG. 16 depicts a precursor structure to the VTFET shown in FIG. 4, after p-type dopant implantation and melt anneal, as seen from cut line 12-12.

### DETAILED DESCRIPTION

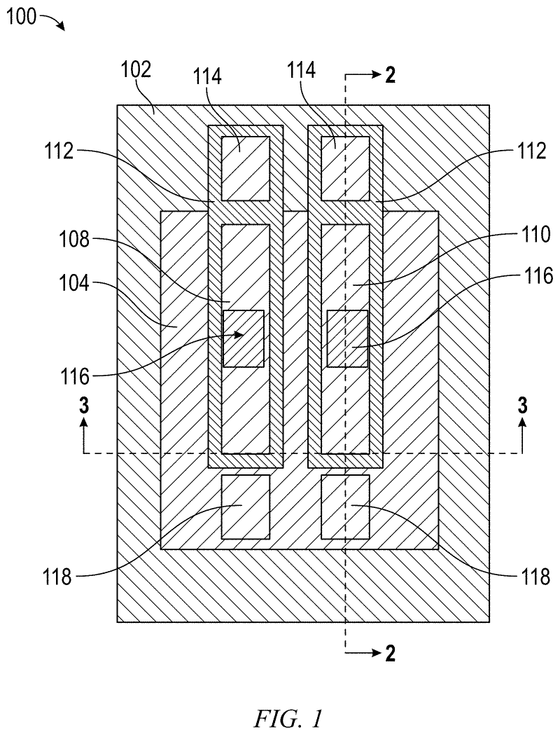

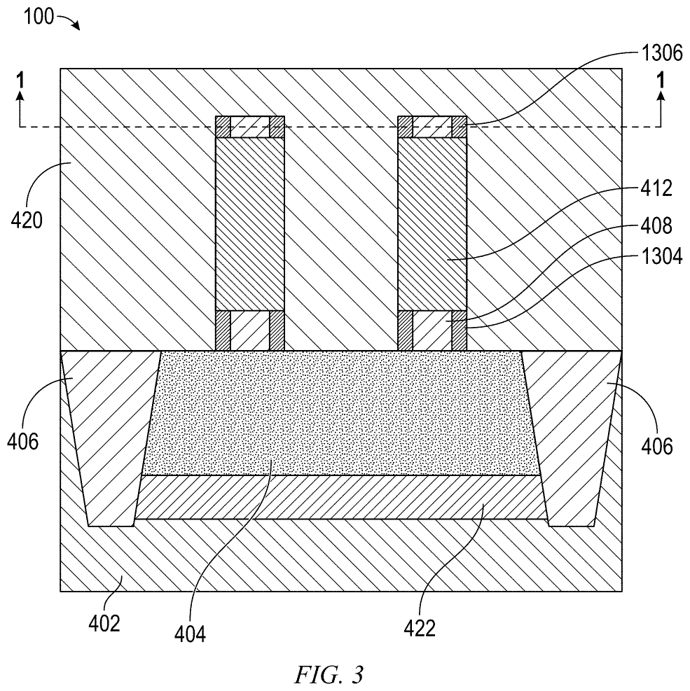

Referring to FIG. 1 through FIG. 3, a vertical transport field effect transistor (VTFET) 100 includes a semiconductor substrate 102, bottom epitaxial silicon (epi-Si) or epitaxial silicon germanium (epi-SiGe) 104 (in one or more embodiments, SiGe with 20-55% Ge), shallow trench isolation dielectric (STI) 106, a semiconductor fin 108 (which acts as a conductive channel in operation of the VTFET 100), top epi-Si or epi-SiGe 110, a gate stack 112 with metallic gate, a metallic gate contact 114, a metallic top contact 116, and a metallic bottom contact 118. Interlayer dielectric 120 surrounds the VTFET 100.

A structural feature that makes the VTFET 100 attractive for areal transistor density scaling is the relative position of metallic contacts 114, 116, 118 and the gate stack 112. In a conventional transistor architecture, S/D contacts are symmetrically placed on opposite sides of the gate stack such that the distance to the transistor channel (a portion of the semiconductor fin 108 that is covered or surrounded by the gate stack) is the same for both S/D contacts. Consequently, S/D resistances between the metallic contacts and the transistor channel are the same on opposite sides of the gate. However, this architecture limits the scaling of the gate-to-gate pitch, due to the presence of S/D contacts in between adjacent gates, thus limiting the overall areal scaling of integrated circuits. The transistor architecture shown in FIG. 1 through FIG. 3 removes the S/D contacts 116/118 from in between adjacent gates 112, as shown in FIG. 1, allowing for a smaller gate-to-gate pitch and a higher overall areal density of integrated circuits.

On the other hand, the metallic contacts 116 and 118 are now asymmetrically placed with respect to the transistor channel, a portion of the semiconductor fin 108 covered by the gate stack 112. Consequently, the S/D resistance between the bottom metallic contact 118 and the transistor channel is substantially larger than the S/D resistance between the top metallic contact 116 and the transistor channel. For a wider Si fin 108, the difference between the bottom S/D resistance and the top S/D resistance becomes larger, thus limiting performance for wide-channel transistors.

The exemplary VTFET 100 is characterized by relatively high resistance between the bottom contact 118 and the fin 108 (bottom source/drain resistance). The bottom resistance depends on geometrical factors and the resistivity of material 104. Geometrical factors include the width of the fin 108 (the fin dimension along its long axis), the size of the contact 118 and its separation from the fin 108, and the thickness and width of material 104. Material for layers 104 and 110 is selected to be compatible with the channel semiconductor material and is typically a highly doped group IV semiconductor such as silicon Si or SiGe.

An amount of electrically active dopant determines the bulk resistivity of layers 104 and 110. The electrically active dopants produce free electrons or holes that make this doped semiconductor material more conductive with reduced bulk resistivity. The amount of electrically activated dopants, or, equivalently, the concentration of free electrons or holes, is limited by thermodynamical laws and is typically referred to as the solid solubility of substitutional dopant phase. Such solid solubility of substitutional dopants depends on the annealing temperature, and peaks at around 100-200° C. below the host semiconductor melting point. Annealing at temperatures below the temperature at which the solid solubility peaks may result in a reduced concentration of free electrons or holes. This phenomenon of reducing active dopants during lower temperature anneals is known as the dopant deactivation process. Because the material 104 of the bottom S/D undergoes multiple anneal cycles while building other features above it, the concentration of free electrons or holes in it is typically below around 3×10²⁰ cm⁻³, the maximum solid solubility of substitutional dopants. In some conventional implementations, the bulk resistivity of the bottom highly-doped Si or SiGe layer 104 is on the order of 300-600μΩ cm, and typically equal to or higher than the bulk resistivity of highly-doped layer 110 of the top source/drain.

When the bulk resistivities are combined with the geometrical factors, the bottom S/D resistance can be several times higher than the top S/D resistance. While a large bottom S/D resistance reduces the overall transistor performance, the large difference between top and bottom S/D resistances makes the transistor operation asymmetric which is also undesirable.

Transistor “ON” resistance, Rₒₙ, and its various components, including the S/D resistances, are measured and partitioned when the transistor is biased in the linear mode of operation. Since the transistor performance is greatly affected by its geometry and scaling, the performance factors such as Rₒₙ are normalized to the transistor footprint (the channel width in the top-down view) or to the effective channel width (the total channel perimeter surrounded by the gate).

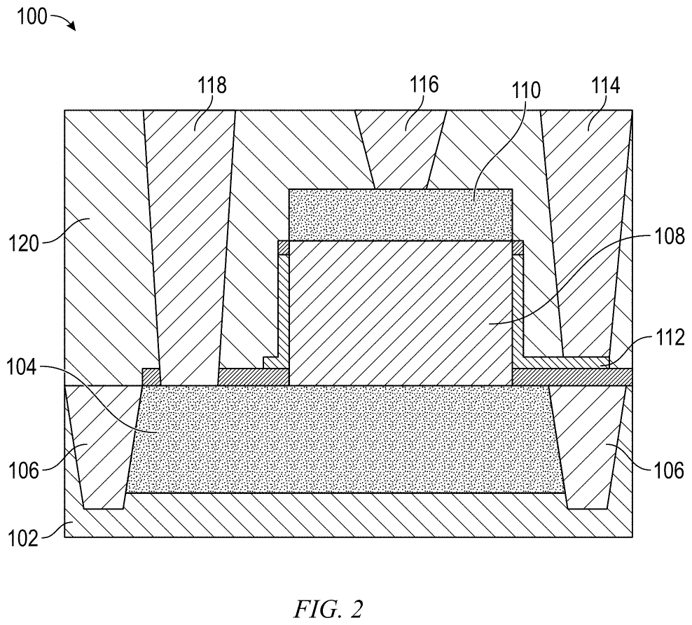

Referring to FIG. 1, the width of each individual fin 108 (the fin dimension along its long axis) constitutes the 1-fin transistor footprint and the perimeter of each individual fin constitutes the 1-fin transistor effective width. In the case of FIG. 1, the effective width is larger than the fin width by more than a factor of 2. For a 2-fin transistor also shown in FIG. 2, the effective width doubles but the increase in its footprint is not that clear because the expansion of the transistor channel occurs in a different dimension.

Due to this reason (the general lack of agreement on accounting for footprint increases), transistor resistances often are normalized by the effective channel width. The normalization procedure includes measuring the total channel perimeter and multiplying measured total “ON” resistance by the total effective channel width. Once Rₒₙ is normalized, all its components, including S/D resistances, are normalized by the same factor. Normalized Rₒₙ can be partitioned into 3 major components: the channel resistance R_{ch}, the contact resistances R_{c}, and the S/D resistances R_{SD}. R_{ch} and R_{c} are measured directly by modulating channel resistance by gate voltage and by accurately determining the voltage drop between the top of metal contacts 118/116 and the S/D layers 104/110 (see FIG. 2), respectively. R_{SD} is derived from these measurements by subtracting R_{ch} and both R_{c} resistances from Rₒₙ. For a typical symmetric S/D configuration, the resistance of the individual source or drain is half of R_{SD} and around an eighth of Rₒₙ, and is typically from about 30Ω μm to about 100Ω μm depending on the exact effective channel width.

For an asymmetric S/D configuration shown in FIG. 2, the bottom S/D resistance is the dominant part of the total R_{SD} and is from about a quarter to about a third of Rₒₙ and typically from about 60Ω μm to about 250Ω μm, depending on the exact effective channel width and R_{c}. Individual contact resistances, including the resistances of respective metallic contact studs 118 and 116, are typically kept below the individual source/drain resistances, such that together, all these external resistive components are less than R_{ch}. In order to accomplish that, the contact resistivity is kept at or below around 3×10⁻⁹Ω cm² in typical S/D contact structures.

According to exemplary embodiments of the invention, highly-doped metastable germanium Ge is buried under the bottom epi-Si or epi-SiGe 104, which can greatly reduce the bottom source/drain resistance due to the significantly lower bulk resistivity of highly-doped metastable germanium, as compared to that of an annealed and stabilized doped epi-Si or epi-SiGe layer, and the ultra-low contact resistivity between these layers. Furthermore, in some embodiments, the highly-doped metastable Ge layer enables a low contact resistance between metallic contact 118 and the source/drain structure. Therefore, in one or more embodiments, the invention provides for a situation in which the resistance from metallic contact 118, through the bottom source/drain structure, to the channel or fin 108, is nearly equal (i.e., in one or more embodiments, equal within about 5%; in one or more embodiments, equal within about 10%) to the resistance from metallic contact 116, through the top source/drain structure, to the fin 108.

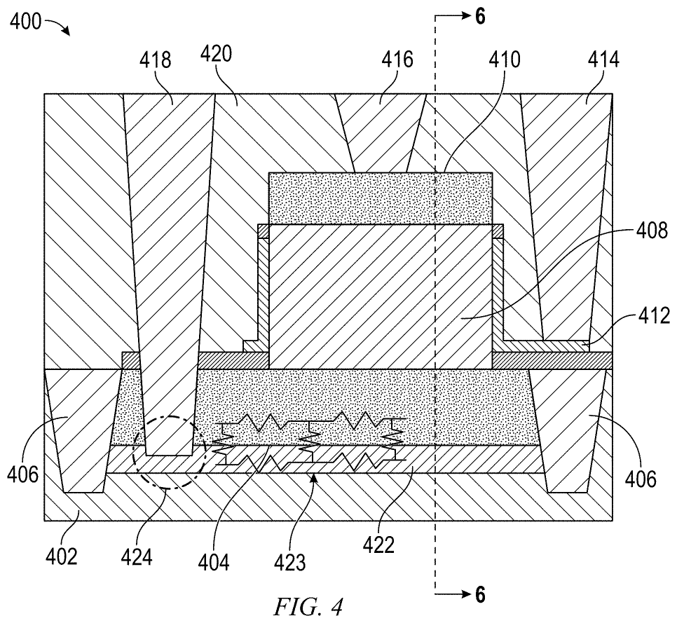

FIG. 4 depicts a sideview of a VTFET 400, according to an exemplary embodiment. The VTFET 400 includes a semiconductor substrate 402 (e.g. a bulk silicon (100)-oriented substrate), bottom epitaxial silicon (epi-Si) or epitaxial silicon germanium (epi-SiGe) source/drain structure 404, shallow trench isolation dielectric (STI) 406, a semiconducting fin 408 (e.g. a Si fin) (which acts as a conducting channel during operation of the VTFET 400, therefore, also referred to herein as a “channel 408”), top epi-Si or epi-SiGe source/drain structure 410, a gate stack 412 including a gate dielectric and a metallic gate (not separately shown), a metallic gate contact 414, a metallic top contact 416, and a metallic bottom contact 418. In one or more embodiments, a conductive path length from the bottom contact 418 through the bottom source/drain structure 404 to the fin 408 is significantly longer (e.g., in one or more embodiments at least 10% longer; in one or more embodiments, at least 20% longer) than a conductive path length from the top contact 416 through the top source/drain structure 410 to the fin 408.

Interlayer dielectric 420 surrounds the VTFET 400. In one or more embodiments, the interlayer dielectric 420 includes a dielectric, e.g., any one or more of silicon oxides, silicon nitrides, titanium oxides, aluminum oxides, aluminum nitrides.

A bypass layer 422 of highly-doped germanium extends from the bottom contact 418 under/alongside the bottom epi-Si/SiGe source/drain structure 404. A small amount of Silicon can be present in the bypass layer 422 making it SiGe with Si content of less than 10 atomic percent (at. %) and preferably less than 5 at. %. Although intentionally alloying Ge with substantial amounts of Si for the bypass layer 422 is not desirable, because it increases the free carrier (electron/hole) scattering, resulting in a higher bulk resistivity of bypass layer 422, a small amount of silicon can inadvertently diffuse from the adjacent layers 404/402 and can beneficially aid in cleaning native surface oxides that may form when the bypass layer is exposed to ambient air. Overall, the silicon content in the bypass layer 422 is substantially lower than the silicon content in the adjacent layers 404/402, resulting in substantially lower melting point of the bypass layer 422. By way of example, the melting point of Si_{0.45}Ge_{0.55} that can be employed for source/drain structure 404 is about 1250° C. while the melting point of Si_{0.05}Ge_{0.95} that can be employed for bypass layer 422 is 980° C.

Bypass layer 422 is electrically isolated from substrate 402 using junction isolation (e.g., doping layer 422 and an underlying portion of substrate 402, the substrate well, with dopants of opposite polarity) or by other known forms of local electrical isolation.

In one or more embodiments, the bypass layer 422 of an n-type VTFET (nVTFET) is doped by n-type dopants such as Phosphorus (P), Arsenic (As), and/or Antimony (Sb) while the underlying substrate well is lightly doped with p-type dopants such as Boron (B). Phosphorus n-type doping is preferred in one or more embodiments due to a higher solid solubility of Phosphorus in Germanium. In one or more embodiments, the bypass layer 422 of a p-type VTFET (pVTFET) is doped by p-type dopants such as Boron, Aluminum (Al), and/or Gallium (Ga) while the underlying substrate well is lightly doped with n-type dopants such as P, As, or Sb. Aluminum and/or Gallium doping is preferred in one or more embodiments due to a higher solid solubility of Aluminum and Gallium in Germanium.

In one or more embodiments, the bypass layer 422 is doped to more than 2 atomic percent with either n- or p-type dopants, i.e. a chemical concentration of dopants in excess of 1×10²¹ atom cm⁻³, with the majority of these dopants being electrically active, i.e. occupying substitutional germanium lattice sites or, equivalently, predominately forming a substitutional dopant phase, thereby producing a metastable alloy under/alongside the bottom epi-Si/SiGe source/drain structure 404 with the free carrier (electron/hole) concentration in excess of 6×10²⁰ cm⁻³ (e.g., a Ge:Al:Ga:B p-type alloy or a Ge:P n-type alloy). Accordingly, the bulk resistivity of the bypass layer 422 is on the order of less than 150 μΩ cm (substantially lower than the bulk resistivity of source/drain structure 404 and comparable to metallic compounds such as titanium nitride or silicide) and the contact resistance between the bypass layer 422 and the epitaxial source/drain structure 404 is less than 3×10¹⁰Ω cm², so that a distributed resistive network 423 that exists between electrically coupled layers 422 and 404 (see FIG. 4) improves the bottom S/D resistance R_{SD} on the order of 25-75%, making it from about a quarter to about an eighth of Rₒₙ and typically from about 30Ω μm to about 100Ω μm, depending on the exact effective channel width.

The reduction in bottom S/D resistance R_{SD} is afforded by the simultaneously low bulk resistivity of bypass layer 422 and its surprisingly low contact resistivity to the S/D structure 404. The ultralow contact resistivity is due to a robust electronic momentum exchange at the unipolar heterojunction of two similar and degenerate semiconductors. It allows for a large portion of electrical current to flow through the bypass layer and then cross into or from the S/D structure 404 in vicinity of the fin/channel 108 without incurring much interfacial resistance.

In typical conventional implementations of bypass layers, the bypass layers are formed on top of epitaxial S/D layers from metallic compounds (e.g. germanosilicides) that have a low bulk resistivity (e.g. below 100 μΩ cm) but a relatively high contact resistivity (e.g. above 5×10⁻⁹Ω cm²) to the S/D structure 404 forcing electrical current to cross from the bypass layer into the S/D epi layer far away from the fin/channel, in order to circumvent the large interfacial resistance and, thus, negating S/D resistive benefits for the S/D geometries shown in FIG. 4. In contrast to conventional implementations, the particular chemical constitution of the exemplary bypass layer 422 also provides good contact resistivity to both the S/D structure 404, e.g., on the order of less than 3×10¹⁰Ω cm² and the bottom contact 418, e.g., on the order of less than 1×10⁻⁹Ω cm².

Chemical concentration of specific dopants in the bypass layer can be uniform or can have a gradient. This depends on processing techniques of chemically introducing and electrically activating dopants of the bypass layer 422. Introducing dopants during epitaxial growth of layer 422 or immediately after epitaxial growth through an ion implantation into entire layer 422 results in a relatively uniform distribution of dopants; however, such early introduction of dopants is practically limited by roughly chemical maximum solubility of dopants in germanium. Dopants in excess of the maximum chemical solubility will precipitate out during long-duration, high-temperature thermal treatments in subsequent processing steps. In one or more embodiments, Al and/or Ga are used to form the bypass layer 422 of a p-type VTFET, due to a high solid solubility in Ge. In one or more embodiments, B also can be used, although its final concentration may be limited because low solid solubility of B in Ge prevents reaching free hole concentration in excess of 6×10²⁰ cm⁻³ from B alone. In one or more embodiments, then, B can be employed in combination with Al and/or Ga. Because Ga or Al precipitates may undesirably react with the adjacent layers, their introduction above the maximum chemical solubility in Ge early in the process flow is not desirable. Excess boron may form electrically inactive but chemically stable B clusters.

Additional dopants can also be introduced late in the process flow through the contact opening.

In the case of ion implantation through the contact opening, the lateral spatial distribution of dopants will be highly nonuniform after implantation, with the majority of dopants located near the opening. Forming metastable Ge-dopant alloy with the concentration of free holes in excess of the 3×10²⁰ cm⁻³ limit is conducted late in the process flow, such that the alloy is never exposed to long-duration anneals higher than 400° C. This can be done, for example, during formation of the bottom contact 418. One method of forming such metastable, highly-activated Ge-dopant alloy uses a nanosecond-scale laser anneal that melts layer 422 without melting the adjacent layers. All dopants mix with the liquid germanium and some of them diffuse appreciable distances within the Ge liquid, making the dopant distribution more uniform. Boron clusters may also dissolve in molten Ge. Diffusivity of B and Al is substantially higher in molten Ge than that of Ga.

Fast crystallization of molten Ge liquid, known as the Liquid Phase Epitaxy (LPE), allows for creating a highly-activated, metastable semiconductor-dopant alloy with concentration of free holes exceeding the 3×10²⁰ cm⁻³ limit, and the subsequent fast temperature quench also allows for preserving this metastable phase. Subsequent anneals do not exceed 400° C. and the metastable alloy remains stable for more than 10 years during pVTFET operation.

Advantageously, a nanosecond-scale anneal allows for forming a highly-activated, metastable semiconductor-dopant alloy through the LPE recrystallization process. The term “laser annealing” denotes an annealing method that employs a laser to induce heat in the surface being treated. A laser is an electro-optical device that emits coherent radiation. In some embodiments, a typical laser emits light in a narrow, low-divergence beam and with a defined wavelength. In some instances, an advantage of employing a laser for the annealing processes is that its light can be easily shaped and focused onto a specific area of the annealing surface, to achieve very high radiation intensity with short exposure durations.

In one or more embodiments, the short exposure duration is achieved by raster scanning a focused laser beam over the substrate surface. In this case, the exposure duration measured at incident intensity at Full Width Half Maximum (FWHM) is the beam width in the scanning direction divided by the scanning velocity. In alternative embodiments, the short exposure duration is achieved by employing a pulsed laser. In this case, the laser beam is shaped to achieve a required peak intensity over a selected substrate area, such as over an entire product die, and the laser is operated in a pulsed mode, such as in the case of a Q-switched laser. The pulse duration of a Q-switched laser at intensity FWHM determines the substrate exposure time. The exposure process is repeated for the entire wafer surface in a step-and-repeat approach. In some embodiments, the exposure to laser light includes 1 pulse to 1000 pulses of light exposure.

The laser type that is employed in the laser annealing method is selected, for example, from a solid-state Nd:YAG laser emitting at 1064 nm and frequency-doubled or -tripled emitting at 532 nm or 355 nm, respectively, or an excimer laser emitting at below 400 nm. In one or more instances, about 40-90% of the incident laser radiation couples into the wafer semiconductor structures within about 10-30 nm of their surfaces.

Once the substrate is exposed to the laser radiation, either through raster scanning or through a laser pulse, its surface temperature begins increasing from its base/preheat value, and falls shortly thereafter. A representative temperature-time trace of a nanosecond laser anneal process includes 4 distinct temperature regions: initial or base substrate temperature, optional preheat portion, heat-up portion, temperature peak point, and cool down portion. Initial or base substrate temperature is, for example, within the range of from 23° C. (room temperature) to 400° C. This temperature is typically set by a hot plate on which the substrate resides. The preheat portion can raise the substrate surface temperature by several hundreds of ° C. from the base temperature for a relatively short duration to ease the energy requirement in the next heating phase while, at the same time, preserving temperature-sensitive elements that may exist in the substrate. This optional heating is typically accomplished with an auxiliary heating device such as a secondary heating laser operating in a millisecond exposure regime. The laser operating in nanosecond-scale duration enables the main heat up portion. The laser beam raises the surface temperature of the substrate from the preheat base or base temperature to the peak, with the ramp-up rate from about 1,000,000,000° C./sec to about 100,000,000,000° C./sec. After laser radiation exposure, the surface temperature quickly drops back to the base temperature, with the temperature ramp down rate of from about 300,000,000° C./sec to about 30,000,000,000° C./sec. The anneal duration measured around the temperature peak point, typically at a level 50° C. below the peak point, ranges from about 1 nanosecond to about 500 nanoseconds, but from around 10 to 100 nanoseconds is more typical. It is customary to specify the process duration of laser anneals in terms of the radiation exposure duration at FWHM rather than the anneal duration at the temperature level 50° C. below the peak temperature. These duration quantities are related to each other and, in some embodiments, the anneal duration is a fraction (e.g. about ⅓) of the radiation exposure duration.

Laser-induced surface temperature rise is set by the laser incident radiation intensity, laser pulse or exposure duration, and substrate thermal and optical properties. The laser radiation is coupled into semiconducting structures, where it is absorbed and converted into heat within 10-30 nm from their respective surfaces, and then the heat quickly spreads, heating up surrounding structures. Hence, short frontside laser exposure causes a non-uniform heating within top structures. The heat penetration depth in the case of nanosecond-scale laser pulses ranges from about 1 micron to about 4 microns in semiconductors and from about 100 nanometers to about 500 nanometers in typical dielectrics. Shorter laser pulses cause high nonuniformity and a higher degree of heating localization. Accordingly, relatively thin semiconductor layers and structures are heated relatively uniformly throughout their entire thickness with a small temperature gradient of ˜0.1-0.3° C./nm while a dielectric thermal isolation induces a temperature gradient of ˜1-3° C./nm. It will be appreciated that the required radiation intensity at which the bypass layer 422 melts (e.g. at around 1000° C.) depends on the surrounding structures, laser pulse duration and energy density, and selected laser wavelength. In some embodiments, the nanosecond laser wavelength is 532 nm, the substrate base temperature is 250° C., the substrate preheat temperature is 500° C., the pulse duration at FWHM is 60 nanoseconds, and the coupled laser energy density at which the bypass layer 422 melts is 70 mJ/cm² (this corresponds to 90 J/cm² of incident laser energy density). While substrate and surrounding structures and the laser parameters may vary, affecting the choice of the incident laser energy density, the range of incident laser energy density from about 30 mJ/cm² to about 3 J/cm² and laser radiation exposure duration from about 10 to 500 nanoseconds can be employed to melt the bypass layer 422 and to form a highly-activated, metastable semiconductor-dopant alloy with concentration of free holes exceeding 3×10²⁰ cm⁻³ limit.

In one or more embodiments, a region 424 of the bypass layer 422 near the bottom contact 418 may have a higher concentration of Ga than the rest of the metastable alloy, which can help to reduce the contact resistivity to below 1×10⁻⁹Ω cm² between the contact and the S/D structure 404.

In one or more embodiments, Al can be first implanted through the contact opening with a dose of up to 1×10¹⁶ cm⁻² and then melt annealed for a short duration (e.g., less than 1 μsec) to diffuse the dopant in the molten bypass layer 422 such that the resultant concentration of Al in the layer is in excess of 1×10²¹ atom cm⁻³. This can be repeated several times, and then Ga can be implanted with a dose of from 1×10¹⁵ to 5×10¹⁵ atom cm⁻² to provide a Ga-rich surface near the contact. After implantation, the Ga also can be melt annealed for short duration. Ga diffusivity in liquid is low relative to Al, and the Ga will stay near the contact.

In one or more embodiments, Phosphorus is used to form the bypass layer 422 of an n-type VTFET, due to a high solid solubility in Ge. In one or more embodiments, As and Sb also can be used, although their final concentration may be limited due to their low solid solubility in Ge, thereby preventing reaching free electron concentration in excess of 6×10²⁰ cm⁻³ from them alone; however, they can be employed in combination with P. High concentrations of P can be introduced into layer 422 during its epitaxial growth, or immediately after epitaxial growth, through an ion implantation, resulting in a relatively uniform distribution of dopants; however, such early introduction of dopants may result in their precipitation during long-duration, high-temperature thermal treatments in subsequent processing steps. Phosphorus precipitates may form electrically inactive, but chemically stable, P clusters. Additional n-type dopants can also be introduced late in the process flow through the contact opening. In the case of ion implantation through the contact opening, the lateral spatial distribution of dopants will be highly nonuniform after implantation, with the majority of dopants located near the opening. Forming metastable Ge-dopant alloy with the concentration of free electrons in excess of 3×10²⁰ cm⁻³ is conducted late in the process flow, such that the Ge:P alloy is never exposed to long-duration anneals higher than 400° C. This is typically done during formation of contact structure 418. One method of forming such metastable, highly-activated Ge-dopant alloy uses a nanosecond-scale laser anneal that melts layer 422 without melting adjacent layers. All dopants mix with the liquid germanium, and Phosphorus will diffuse appreciable distances within the Ge liquid, making Phosphorus distribution more uniform. Phosphorus clusters may also dissolve in molten Ge. Fast LPE allows for creating a highly-activated, metastable n-type Ge-dopant alloy (e.g. Ge:P alloy) with concentration of free electrons exceeding the 3×10²⁰ cm⁻³ limit, and the subsequent fast temperature quench also allows for preserving this metastable phase. Laser annealing conditions that enable fast LPE and an appropriate temperature quench are the same as for p-type VTFET embodiments described above. Subsequent anneals do not exceed 400° C. and the metastable alloy remains stable for more than 10 years during nVTFET operation.

In one or more embodiments, Phosphorus can first be implanted through the contact opening, with a dose of up to 1×10¹⁶ cm⁻², and then melt-annealed for a short duration (e.g., less than 1 μsec), to diffuse the dopant in the molten bypass layer 422 such that the resultant concentration of Phosphorus in the layer is in excess of 1×10²¹ atom cm⁻³. This can be repeated several times. In some embodiments, the contact 118 can be made directly to the n-type bypass layer 422 with the contact resistivity below 2×10⁻⁹Ω cm².

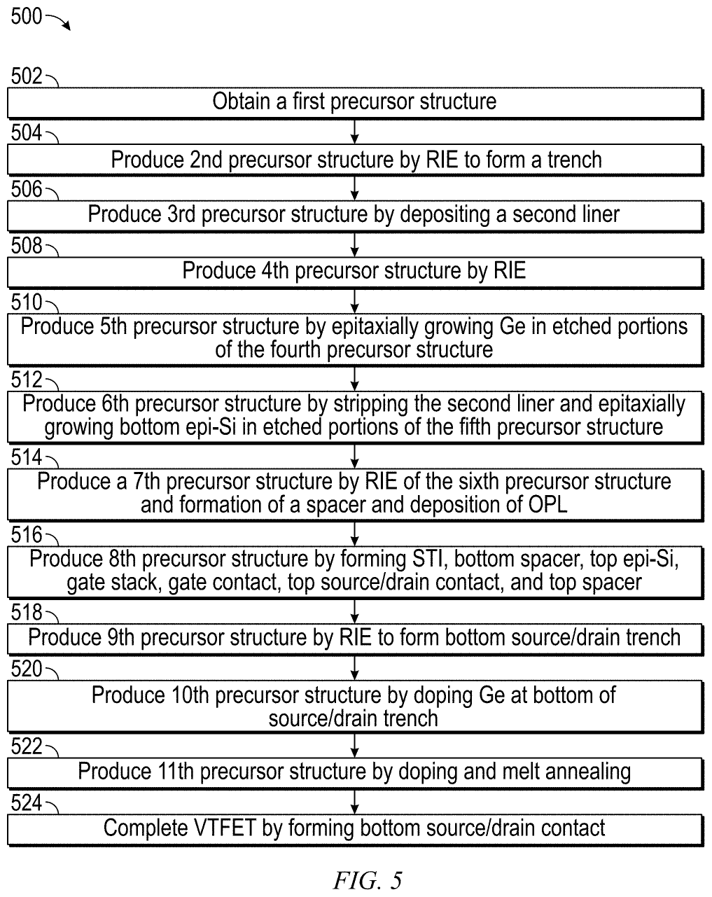

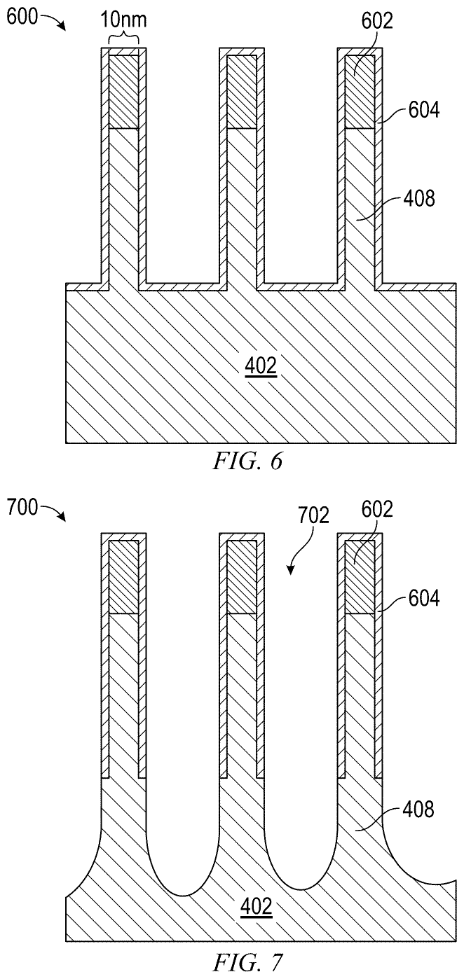

FIG. 5 shows a flowchart of a process 500 for fabrication of the VTFET 400. FIG. 6 through FIG. 16 show precursor structures 600 through 1600 that result from steps in the process.

Referring to FIG. 5, at step 502 of the process, obtain a first precursor structure 600 (shown in FIG. 6) that includes substrate 402, fin 408, hard mask 602, and a first liner 604 (e.g., a silicon-nitride liner). The first precursor structure 600 can be formed by conventional processes, some of which are further discussed below. The first precursor structure 600 may also include useful features (not shown) such as substrate dopant wells.

At 504, produce a second precursor structure 700 (shown in FIG. 7) by reactive ion etching (ME) the first precursor structure 600 to form a trench 702 where the liner 604 is partly removed. The RIE of step 504 can use, but not limited to, CF₄, He, Argon, SF₆, CHF₃, O₂.

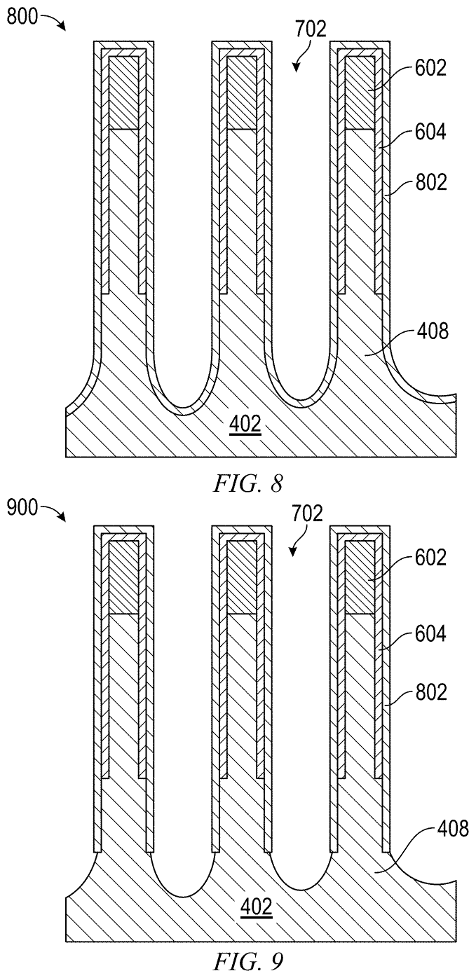

At 506, produce a third precursor structure 800 (shown in FIG. 8) by depositing a second liner 802 (e.g., a silicon-oxide liner) onto the second precursor structure 700.

At 508, produce a fourth precursor structure 900 (shown in FIG. 9) by ME the third precursor structure 800 to remove lower portions of the second liner 802 at the bottom of the trench 702. The RIE of step 508 can use similar chemistry as step 504.

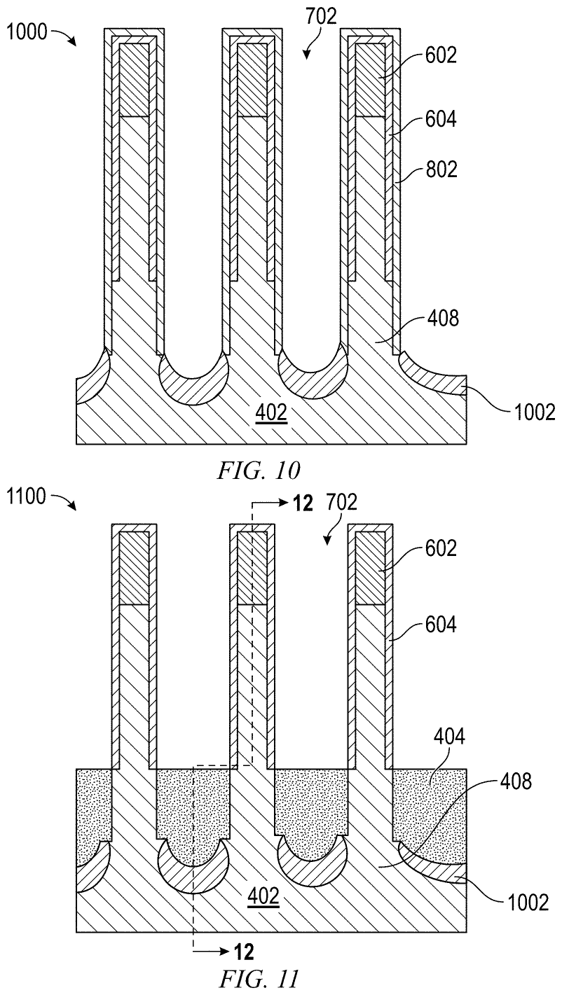

At 510, produce a fifth precursor structure 1000 (shown in FIG. 10) by epitaxially growing germanium (Ge) 1002 in the etched portions of the fourth precursor structure 900. Epitaxially growing germanium (Ge) 1002 can be conducted simultaneously or sequentially for respective n-type and p-type devices. Sequential epitaxial growth involves forming blocking hardmasks using conventional patterning techniques. In this case, a first set of devices (e.g. nFETs) are blocked with a hardmask (typically a dielectric liner such as silicon nitride) while exposing the second set of devices (e.g. pFET) for epitaxial growth. If the Ge layer is grown sequentially for different device types, the first set of different-polarity dopants can be introduced during the epitaxial growth for each epitaxial layer. If the Ge layer is grown simultaneously for different device types, it is typically grown undoped. Then, the first set of dopants can be introduced through blocked ion implantation and conventional annealing. Blocked ion implantation employs a softmask formed by conventional patterning techniques prior to implantation. Softmask is then stripped and the process is repeated for a different device type. After the doping process is completed, a conventional anneal step is added to anneal out any implantation damage. A sequential epitaxial growing approach allows for forming Ge epitaxial layers for different or select device types. For instance, it can be formed only for pFETs or it can be formed for both nFETs and pFETs with correct doping polarity for each device type.

At 512, produce a sixth precursor structure 1100 (shown in FIG. 11) by stripping the second liner 802 and epitaxially growing bottom epi-Si or epi-SiGe 404 in the etched portions of the fifth precursor structure 1000. Again, epi-Si or epi-SiGe 404 can be grown sequentially for different device types employing blocking hardmasks. These can be the same hardmasks used for the fifth precursor structure 1000 or different ones. Sequential epitaxial growth with in-situ doping allows for correct doping polarity for different device types. Stripping of the second liner can use, for example, wet etch process such as diluted HF or phosphoric acid.

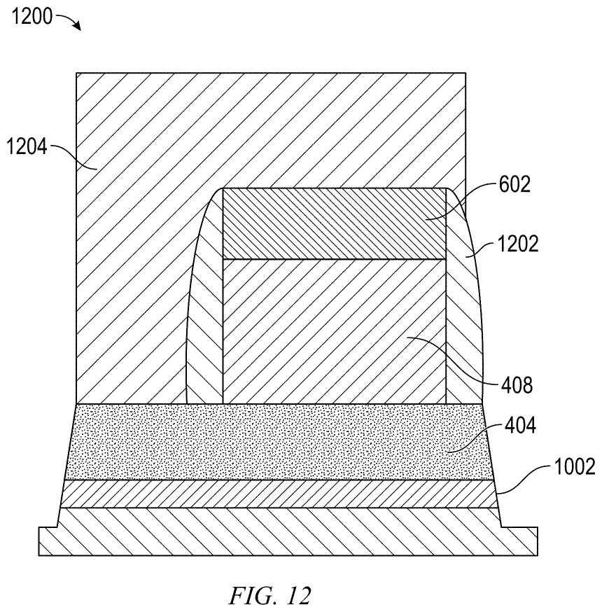

At 514, produce a seventh precursor structure 1200 (shown in FIG. 12) by trench RIE of the sixth precursor structure 1100 (to form trenches for shallow trench isolation to be deposited in a subsequent step) and subsequent formation of a spacer 1202 and deposition of an optical planarization layer 1204.

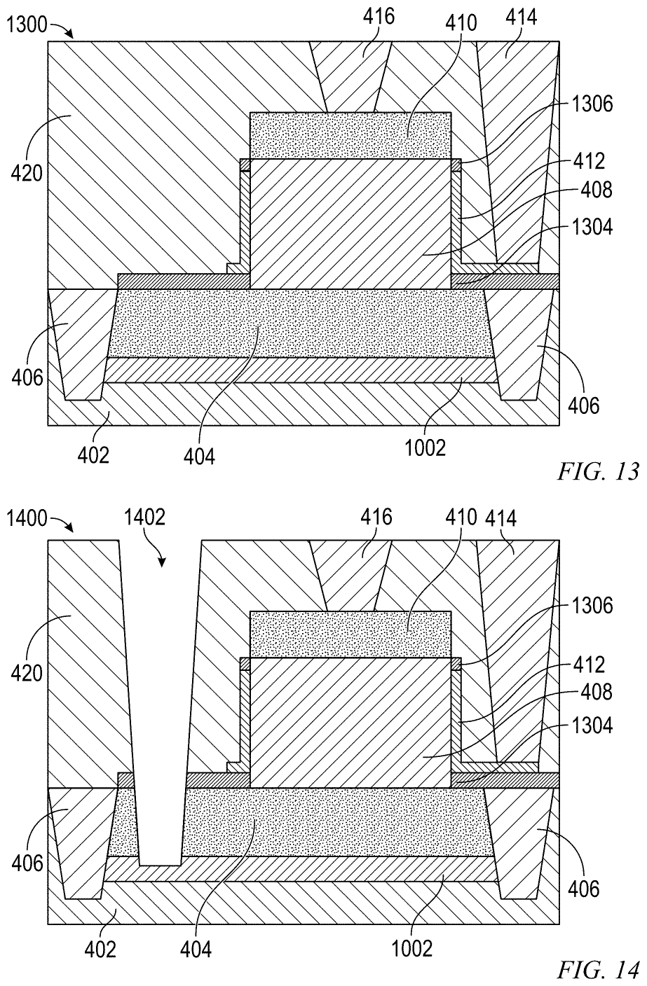

At 516, produce an eighth precursor structure 1300 (shown in FIG. 13) by formation of shallow trench isolation (STI) 406, bottom spacer 1304, top semiconductor source/drain structure 410, gate stack 412 (composed of one or more work function metals, further discussed below), gate contact 414, top source/drain contact 416 (composed of one or more contact materials, further discussed below), interlayer dielectric 420, and top spacer 1306.

After step 516, the process has formed the asymmetric semiconductor precursor structure 1100 that includes: a fin 408 that has an upper portion and a base; a top source/drain structure 410 that touches the upper portion of the fin; a bottom source/drain structure 404 that touches the base of the fin, wherein the top source/drain structure is smaller than the bottom source/drain structure; and a germanium-containing layer 1002 within the bottom source/drain structure.

At 518, produce a ninth precursor structure 1400 (as shown in FIG. 14) by RIE of the eighth precursor structure 1300 to form a bottom source/drain trench 1402.

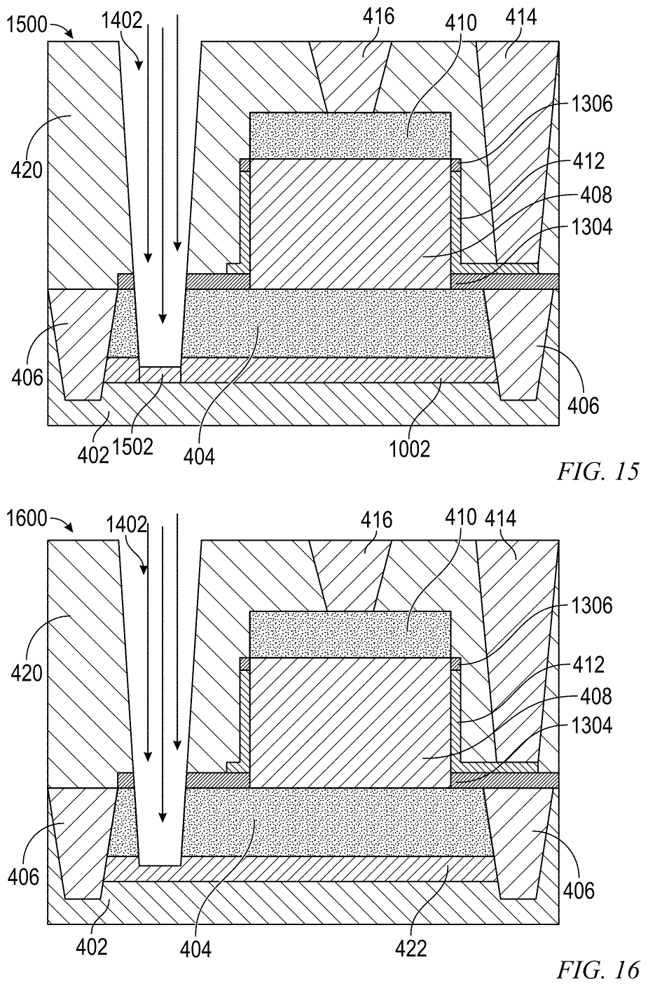

At 520, produce a tenth precursor structure 1500 (as shown in FIG. 15) by doping the germanium 1002 at the bottom of the source/drain trench 1402 to form a doped germanium region 1502. This allows placing an additional set of dopants into the layer 1002. The doping technique includes, for example, ion implantation and/or an epitaxial growth through the trench 1402 with in-situ doping. Furthermore, a portion of layer 1002 can be selectively removed with respect to the adjacent layers using, for instance, HCl vapors, and replaced with an epitaxially grown film with in-situ doping. Both the epitaxy and ion implantation through trench 1402 can be conducted sequentially for different device types using appropriate hard and soft masks to form highly doped Ge regions 1502 and 1002 of correct polarity for different device types.

At 522, produce an eleventh precursor structure 1600 (as shown in FIG. 16) by melt-annealing region 1502 with layer 1002 to form a metastable Ge-dopant alloy layer (bypass layer) 422.

At 524, complete the VTFET 400 (as shown in FIG. 4) by forming the bottom source/drain contact 418 using known metallization techniques. Metallic contacts 414, 416, and 418 can be then wired into desired integrated circuits using the wiring network of back-end-of-line (BEOL) metal interconnects.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures.

In one or more embodiments, work function metal (WFM) layers are disposed over the gate dielectric layer in both the nFET and pFET regions (in embodiments having both types of regions) to complete the gate stacks. Non-limiting examples of suitable work function (gate) metals include p-type work function metal materials and n-type work function metal materials. P-type work function materials include compositions such as ruthenium, palladium, platinum, cobalt, nickel, and conductive metal nitrides like TiN, WN, or any combination thereof. N-type metal materials include compositions such as hafnium, zirconium, titanium, tantalum, aluminum, metal carbides (e.g., hafnium carbide, zirconium carbide, titanium carbide, and aluminum carbide), aluminides, or any combination thereof.

The work function metal(s) may be deposited by a suitable deposition process, for example, atomic layer deposition (ALD), chemical vapor deposition (CVD), plasma enhanced CVD (PECVD), physical vapor deposition (PVD), plating, and thermal or e-beam evaporation. Pinch-off of work function metal material between semiconductor fins is essentially avoided during deposition. The WFM layer is removed from one of the nFET and pFET regions in structures including both types of regions, while the other region is protected. An SC1 etch, an SC2 etch or other suitable etch processes (discussed below) can be employed to remove the selected portion of the originally deposited WFM layer. A new WFM layer suitable for the region is then deposited. A device formed in the nFET region will accordingly include a WFM layer (gate electrode) having a first composition while a device in the pFET region will have a WFM layer having a second composition. For example, the WFM employed in an nFET region may be a Ti, Al, TiAl, TiAlC or TiAlC layer or a metal stack such as TiN/TiAl/TiN, TiN/TiAlC/TiN, TiN/TaAlC/TiN, or any combination of an aluminum alloy and TiN layers. The WFM layer employed in the pFET region may, for example, be a TiN, TiC, TaN or a tungsten (W) layer. The threshold voltage (Vt) of nFET devices is sensitive to the thickness of work function metals such as titanium nitride (TiN).

A number of different precursors may be used for the epitaxial deposition of the in situ doped semiconductor material. In some embodiments, the gas source for the deposition of an epitaxially formed in situ doped semiconductor material may include silicon (Si) deposited from silane, di silane, trisilane, tetrasilane, hexachlorodisilane, tetrachlorosilane, dichlorosilane, trichlorosilane, disilane and combinations thereof. In other examples, when the in situ doped semiconductor material includes germanium, a germanium gas source may be selected from the group consisting of germane, digermane, halogermane, dichlorogermane, trichlorogermane, tetrachlorogermane and combinations thereof. Examples of other epitaxial growth processes that can be employed in growing semiconductor layers described herein include rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE).

By “in-situ” it is meant that the dopant that dictates the conductivity type of doped layer is introduced during the process step, for example epitaxial deposition, that forms the doped layer. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has the same crystalline structure and orientation as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

As used herein, the term “conductivity type” denotes a dopant region being p-type or n-type. As further used herein, “p-type” refers to the addition of impurities to an intrinsic semiconductor that creates deficiencies of valence electrons. In a silicon-containing substrate, examples of p-type dopants, i.e., impurities include but are not limited to: boron, aluminum, gallium and indium. As used herein, “n-type” refers to the addition of impurities that contribute free electrons to an intrinsic semiconductor. Examples of n-type dopants, i.e., impurities in a silicon-containing substrate include but are not limited to antimony, arsenic and phosphorous.

Contact material may, for example, include tantalum (Ta), aluminum (Al), platinum (Pt), gold (Au), titanium (Ti), palladium (Pd) or any combination thereof. The contact material may be deposited by, for example, CVD, PECVD, PVD, plating, thermal or e-beam evaporation, or sputtering. A planarization process such as chemical-mechanical polishing (CMP) is performed to remove any electrically conductive material (overburden) from the top surface of the structure.

As an exemplary subtractive process, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (ME), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Given the discussion thus far, it will be appreciated that, in general terms, an exemplary semiconductor structure, according to an aspect of the invention, includes a gate stack 412 that surrounds a semiconductor channel 408; a first semiconductor source/drain 410; a first metallic contact 416 that touches the first source/drain; a second semiconductor source/drain 404; and a second metallic contact 418 that touches the second source/drain. A conductive path length from the channel to the first metallic contact through the first source/drain is smaller than a conductive path length from the channel through the second source/drain to the second metallic contact. The second source/drain includes a bypass layer 422 that touches the second metallic contact, and the bypass layer includes a metastable alloy of two or more elements of semiconductors and dopants.

In one or more embodiments, the bypass layer is electrically coupled to the second source/drain with an interfacial resistance of less than 3×10¹⁰ Ohm cm².

In one or more embodiments, the bypass layer includes germanium. In one or more embodiments, the bypass layer includes boron. In one or more embodiments, the bypass layer includes at least one of gallium and aluminum. In one or more embodiments, the bypass layer includes aluminum diffused through the bypass layer in a concentration no less than 1×10²¹ atoms per cubic centimeter and gallium in a concentration no less than 1×10²¹ atoms per cubic centimeter. In one or more embodiments, gallium in the bypass layer is localized to a region that touches a metallic contact, and the region that touches the metallic contact exhibits contact resistivity of less than 10⁻⁹Ω cm².

In one or more embodiments, the bypass layer includes phosphorus. In one or more embodiments, the bypass layer includes at least one of antimony and arsenic. In one or more embodiments, antimony in the bypass layer is localized to a region that touches a metallic contact, and the region that touches the metallic contact exhibits contact resistivity of less than 10⁻⁹Ω cm².

In one or more embodiments, the resistance from the first metallic contact through the first source/drain to the channel is nearly equal to the resistance from the second metallic contact through the second source/drain to the channel.

According to another aspect, an exemplary semiconductor structure 400 includes a semiconductor substrate 402; a semiconductor fin 408 protruding from the substrate; a top semiconductor source/drain structure 410 at an upper end of the fin away from the substrate; a bottom semiconductor source/drain structure 404 in the substrate adjacent to and partly underlying the fin; a gate stack 412 surrounding vertical sides of the fin between the top semiconductor layer and the bottom semiconductor layer; an interlayer dielectric 420 surrounding the fin and the gate stack; a metallic top contact 416 penetrating the interlayer dielectric and touching the top semiconductor layer; a metallic gate contact 414 penetrating the interlayer dielectric and touching the gate stack; a bypass layer 422 partly underlying the fin and touching the bottom semiconductor layer; and a metallic bottom contact 418 penetrating the interlayer dielectric and touching the bypass layer. The bypass layer includes a metastable alloy of two or more elements of semiconductors and dopants.

The metastable alloy of the bypass layer may be constituted of component elements similar to the metastable alloy described with reference to other aspects of the invention.

According to another aspect, an exemplary method includes forming an asymmetric semiconductor structure. The asymmetric semiconductor structure has a fin that has an upper portion and a base; a top source/drain structure that touches the upper portion of the fin; and a bottom source/drain structure that touches the base of the fin. The top source/drain structure is smaller than the bottom source/drain structure. The asymmetric semiconductor structure also includes a germanium-containing bypass layer within the bottom source/drain structure. The method further includes alloying the germanium-containing bypass layer with a dopant to form a metastable semiconductor-dopant alloy, forming a top metallic contact that touches the top source/drain structure at a first conductive path length from the fin, and forming a bottom metallic contact that touches the bypass layer at a second conductive path length from the fin. Although the second conductive path length is significantly longer than the first conductive path length, the bypass layer is effective to reduce resistance along the second conductive path length so that a resistance from the bottom metallic contact to the fin is nearly equal to a resistance from the top metallic contact to the fin.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1st Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
a gate stack surrounding a semiconductor channel;
a first semiconductor source/drain;
a first metallic contact that touches the first source/drain;
a second semiconductor source/drain; and
a second metallic contact that touches the second source/drain, wherein a conductive path length from the channel to the first metallic contact through the first source/drain is smaller than a conductive path length from the channel through the second source/drain to the second metallic contact;
wherein the second source/drain comprises a bypass layer that touches the second metallic contact, and wherein the bypass layer comprises a metastable alloy of two or more elements of semiconductors and dopants.

2. The semiconductor structure of claim 1, wherein the bypass layer is electrically coupled to the second source/drain with an interfacial resistance of less than 3×10⁻¹⁰ Ohm cm².

3. The semiconductor structure of claim 1, wherein the bypass layer comprises germanium.

4. The semiconductor structure of claim 3, wherein the bypass layer comprises boron.

5. The semiconductor structure of claim 3, wherein the bypass layer comprises at least one of gallium and aluminum.

6. The semiconductor structure of claim 5, wherein the bypass layer comprises aluminum diffused through the bypass layer in a concentration no less than 1×10²¹ atoms per cubic centimeter and gallium in a concentration no less than 1×10²¹ atoms per cubic centimeter.

7. The semiconductor structure of claim 5, wherein gallium in the bypass layer is localized to a region that touches the second metallic contact, and the region that touches the second metallic contact exhibits contact resistivity of less than 10⁻⁹Ω cm².

8. The semiconductor structure of claim 3, wherein the bypass layer comprises phosphorus.

9. The semiconductor structure of claim 8, wherein the bypass layer comprises at least one of antimony and arsenic.

10. The semiconductor structure of claim 9, wherein antimony in the bypass layer is localized to a region that touches the second metallic contact, and the region that touches the second metallic contact exhibits contact resistivity of less than 10⁻⁹Ω cm².

11. The semiconductor structure of claim 1, wherein the resistance from the first metallic contact through the first source/drain to the channel is nearly equal to the resistance from the second metallic contact through the second source/drain to the channel.

12. A semiconductor structure comprising:
a semiconductor substrate;
a semiconductor fin, protruding from the substrate;
a top semiconductor layer at an upper end of the fin away from the substrate;
a bottom semiconductor layer in the substrate adjacent to and partly underlying the fin;
a gate stack surrounding vertical sides of the fin between the top semiconductor layer and the bottom semiconductor layer;
an interlayer dielectric surrounding the fin and the gate stack;
a metallic top contact penetrating the interlayer dielectric and touching the top semiconductor layer;
a metallic gate contact penetrating the interlayer dielectric and touching the gate stack;
a bypass layer partly underlying the fin and touching the bottom semiconductor layer; and
a metallic bottom contact penetrating the interlayer dielectric and touching the bypass layer,
wherein the bypass layer comprises a metastable alloy of two or more elements of semiconductors and dopants.

13. The semiconductor structure of claim 12, wherein the bypass layer comprises germanium.

14. The semiconductor structure of claim 13, wherein the bypass layer comprises boron.

15. The semiconductor structure of claim 14, wherein the bypass layer comprises at least one of aluminum and gallium.

16. The semiconductor structure of claim 15, wherein the bypass layer comprises aluminum diffused through the bypass layer in a concentration no less than 1×10²¹ atoms per cubic centimeter and gallium in a concentration no less than 1×10²¹ atoms per cubic centimeter.

17. The semiconductor structure of claim 13, wherein the bypass layer comprises phosphorus.

18. The semiconductor structure of claim 17, wherein the bypass layer comprises at least one of antimony and arsenic.

19. The semiconductor structure of claim 18, wherein antimony in the bypass layer is localized to a region that touches the metallic bottom contact, and the region that touches the metallic bottom contact exhibits contact resistivity of less than 10⁻⁹Ω cm².

20. A method comprising:
forming an asymmetric semiconductor structure that comprises:
a fin that has an upper portion and a base;
a top source/drain structure that touches the upper portion of the fin;
a bottom source/drain structure that touches the base of the fin, wherein the top source/drain structure is smaller than the bottom source/drain structure; and
a germanium-containing bypass layer within the bottom source/drain structure;
alloying the germanium-containing bypass layer with a dopant to form a metastable semiconductor-dopant alloy;
forming a top metallic contact that touches the top source/drain structure at a first conductive path length from the fin,
forming a bottom metallic contact that touches the bypass layer at a second conductive path length from the fin; and
wherein the second conductive path length is significantly longer than the first conductive path length, but the bypass layer is effective to reduce resistance along the second conductive path length so that a resistance from the bottom metallic contact to the fin is nearly equal to a resistance from the top metallic contact to the fin.
